(19) United States
(12) Patent Application Publication
(10) Pub. No.: US 2008/0288191 A1
(43) Pub. Date: Nov. 20, 2008

(54) Method for Production of a Data Record and a Field Device, as Well as a System for Recording the Electrical Power Quality of a Power Supply System

(75) Inventor: Andreas Jurisch, Schwante (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, Munich (DE)

(21) Appl. No.: 12/091,355

(22) PCT Filed: Oct. 25, 2005
(86) PCT No.: PCT/DE2005/001937

§ 371 Date: Apr. 24, 2008

(51) Int. Cl. G01R 21/06; G06F 17/18

(52) U.S. Cl. 702/60; 702/179

(57) ABSTRACT

A method of generating a data record, which indicates a deviation of alternating current and/or AC voltage values present at a measurement location of a power supply system from their expected temporal profile. In order to enable such a deviation to be specified in an even more accurate manner, the following steps are carried out: measured values representing the alternating current and/or AC voltage values at the measurement location of the power supply system are recorded; an event signal is generated if the measured values deviate from their expected temporal profile; when an event signal is present, a set of state parameters which describe a state of the power supply system at the measurement location is determined from the measured values and from further measured values which follow the measured values during a predeterminable measurement period, and at least some of the state parameters in the set are assigned to an associated cause character string that indicates a cause of the deviation, and the data record is generated from at least the set of parameters and the cause character string. The invention also relates to an electrical field device and to a system for detecting the quality of electrical power from the power supply system.

In electrical power supply systems, so-called fault recorders are used to monitor the quality of the electrical power being produced by the power supply system. Fault recorders may in this case be in the form of so-called field devices which are arranged in the vicinity of a measurement point in the power supply system. The quality of the electrical power at this measurement point is in this case established using specific quality parameters, such as the component of discrepancies between the time profiles of current and voltage values and their expected profile in terms of frequency, amplitude and phase. The component of harmonics, the stability of a mean value of the current and/or voltage values and the transmitted power may also represent quality parameters such as these.

Fault recorders are known, for example, from the Siemens Catalogue “Digitaler Störschreiber SIMEAS R, Power Quality Katalog SR 10.1.1, 2004” [Simeas R digital fault recorder, Power Quality Catalogue SR 10.1.1,2004]. In order to determine the electrical power quality in a power supply system, the known fault recorders record alternating-current and AC voltage values at the measurement point in the electrical power supply system, and produce measured values proportional to them. The quality parameters mentioned are formed from these measured values. Discrepancies between the quality parameters and their desired profile are stored in event records and can be transmitted for evaluation purposes to external devices, such as evaluation computers. An evaluation computer such as this can use the event record to determine the level of the electrical power quality of the power supply system. For example, for this purpose, it is possible to investigate whether the profile of the quality parameters is within the ranges required by specific standards, such as EN 50160.

The evaluation of the determined quality parameters can also be assisted by specific methods, by means of which the effects of discrepancies in the quality parameters can be estimated. For this purpose, by way of example, the magnitudes of positive discrepancies of a measured voltage mean value (the so-called Swells) or negative discrepancies from this mean value (the so-called Sags) can be plotted on a graph over the time of the respective discrepancy. Characteristics which have been specified by the ITIC (Information Technology Industries Council), for example, can be used to determine whether the measured discrepancy is, in particular, hazardous to information technology devices.

The object of the invention is to specify a method, a field device and a system by means of which discrepancies in the electrical power quality in a power supply system can be specified even more accurately.

With regard to the method, this object is achieved by proposing a method for production of a data record which indicates a discrepancy between alternating-current and/or AC voltage values at a measurement point in a power supply system and their expected time profile, with the following steps being carried out in the method: recording of measured values which indicate the alternating-current and/or AC voltage values at the measurement point in the power supply system; production of an event signal if the measured values differ from their expected time profile; when an event signal is present, determination of a parameter set of state parameters (which describe a state of the power supply system at the measurement point) from the measured values and from further measured values which follow these measured values during a predeterminable event time duration, and association of at least some of the state parameters in the parameter set with an associated cause character string which indicates a cause of the discrepancy, and production of the data record from at least the parameter set and the cause character string.

The major advantage of the method according to the invention is that it does not just result in production of the basic state parameters which describe the instantaneous state of the electrical power supply system during a discrepancy, but a data record is also output, indicating the cause of the detected discrepancy on the basis of the cause character string. This allows the operator of the electrical power supply system to find the source of a fault in the electrical power supply system, which has led to the discrepancy, considerably more quickly. If required, appropriate measures can be taken in real time to overcome the fault source. Possible causes which may lead to a discrepancy in the state parameters are, for example, faults (for example shorts), the starting of electric motors, transformers being started up, continuing faults or self-correcting faults. In this case, it should be noted that the state parameters may be both specific calculated values, such as a discrepancy in the frequency of the measured values, and values of a more descriptive nature, for example the indication that harmonics are in fact present.

One advantageous development of the method according to the invention provides that the measured values are in each case recorded during an averaging period and a mean value is formed from the measured values recorded during the averaging period, and the difference between this mean value and an expected value is formed, with the expected value indicating an expected value of the mean value which has been determined with respect to the actual mean value of mean values from previous times, and the event signal which indicates a discrepancy in the mean value is produced if the difference exceeds a predetermined threshold value. This allows any discrepancy to be detected, and the event signal to be produced, particularly reliably. For this purpose, a mean value may, for example, be a so-called RMS (root mean square) value of the recorded measured values.

The averaging period may in this context, for example, be half the oscillation period of the measured alternating current or of the measured AC voltage. On the one hand, a sufficiently large number of measured values are made available in this way as the basis for the averaging process and, on the other hand, a result can be determined relatively quickly.

One further advantageous development of the method according to the invention provides that the state parameters are associated with the cause character string by using an electronic database in which in each case one cause character string is associated with an associated comparison set of state parameters, and the data record is produced from that cause character string whose associated comparison set matches the determined parameter set.

This allows the parameter set to be associated particularly easily with a corresponding cause character string. For this purpose, the electronic database has comparison sets of state parameters which are associated with cause character strings. By way of example, the cause character string comprises a string variable whose contents indicate the cause of the discrepancy, for example “starting of an electric motor”. However, it may also contain just any given sequence of indications from which a message that a person can understand is then obtained. During the process of comparing the parameter set of the actually present state parameters with the individual comparison sets of those state parameters from the electronic database, a search is carried out for a match between the parameter set and the comparison set and, if a match is found, the cause character string appropriate to that discrepancy is read from the database.

A further advantageous embodiment of the method according to the invention provides that the parameter set also indicates harmonic oscillations of the fundamental frequency of the measured values. As mentioned, this allows a specific statement to be made that a harmonic has occurred or else just an indication that such a harmonic is present. It is also possible to provide that in the case of a three-phase power supply system, the parameter set also indicates balanced components of the measured values. Balanced components are the zero phase sequence component, the positive phase sequence components and the negative phase sequence components in the three-phase system. Once again, in order to indicate the balanced components, either the individual components are calculated specifically or an indication is, for example, just given that the power supply system is in an unbalanced state at the measurement point (the zero phase sequence component is in this case not equal to zero).

A further advantageous embodiment of the method according to the invention provides that an event time duration is determined during which the discrepancy is present, and the parameter set also indicates the event time duration. An event time duration such as this is helpful, for example, for subsequent analyses of the discrepancies.

A further advantageous embodiment to the method according to the invention provides that at least some of the state parameters in the parameter set are used to produce an effective character string which indicates an effect of the discrepancy, and the data record is produced taking into account the effect character string. By way of example, the initially mentioned method based on ITIC characteristics may be used for this purpose, according to which a graph, on which the magnitude of the discrepancy in the mean value of the voltage measured values is plotted against the time duration of the discrepancy, can be used to determine the level of the discrepancy. This makes it possible to determine how hazardous the discrepancies are for connected electrical devices.

A further advantageous embodiment of the method according to the invention, finally, provides that the method is carried out at a plurality of measurement points in the power supply system, and the data records produced at the individual measurement points are combined to form an overall data record. This allows an overall overview of a plurality of measurement points in the electrical power supply system to be produced in a simple manner. The overall data record may, for example, be transmitted to a system control center, in which the electrical power supply system is monitored and controlled.

With regard to the field device, the abovementioned object is achieved by a field device for recording the electrical power quality at a measurement point in a power supply system having a measurement device for recording measured values which indicate an alternating current and/or an AC voltage, an event identification device which uses the measured values to identify any discrepancy between the alternating current and/or the AC voltage and an expected profile, a parameter calculation device for determination of a parameter set of state parameters from the measured values and from further measured values which follow these measured values during a predeterminable measurement period, with the state parameters indicating the state of the power supply system at the measurement point, a cause identification unit which allocates a cause character string, indicating the cause of the discrepancy, when there is a discrepancy of the parameter set, and an output unit, which outputs a data record which is formed taking into account at least some of the state parameters in the parameter set and the cause character string.

The field device according to the invention allows a cause character string to be determined in a simple manner, indicating a possible cause of the discrepancy between the state parameters and their expected values. This provides the operator of the power supply system with the capability to identify, and if necessary to rectify, fault sources in the power supply system quickly.

In this context, it is regarded as an advantageous development of the electrical field device that a computation unit is provided in order to determine a mean value of the recorded measured values, and the event identification device identifies any discrepancy between the mean value and its expected profile. This allows a discrepancy to be deduced on the basis of a simple averaging process.

Furthermore, a further advantageous embodiment of the field device according to the invention consists in that the cause identification unit has an electronic database in which in each case one cause character string is associated with an associated comparison set of state parameters. The cause character string can be associated comparatively easily with the corresponding state parameters in the parameter set by means of the database.

A further advantageous embodiment of the field device according to the invention consists in that the field device has an effect identification device which uses at least some of the state parameters to produce an effect character string which indicates an effect of the discrepancy. This makes it possible to output not only the cause but also any effect of the discrepancy that has been identified with the data record produced. Any effect may be determined, for example, using the ITIC characteristics as explained above. This provides the operator of the electrical power supply system with comprehensive information relating to discrepancies that have occurred.

Furthermore, a further advantageous embodiment of the field device according to the invention provides that the output unit of the field device has a data interface via which the data record is emitted. This data interface may advantageously be an IP-compatible interface, for example an Ethernet interface. This makes it possible to include the field device according to the invention in an IP-compatible network. An IP-compatible network is a network in which data messages can be transmitted using the IP protocol. One such network, for example, is an Ethernet network in which data can be transmitted, for example, using IEC Standard 61850.

The abovementioned object is also achieved by a system for recording the electrical power quality of a power supply system having a plurality of field devices as claimed in one of claims 10 to 15, with the field devices being connected to one another via a communication network. This allows the individual field devices to identify very easily whether discrepancies have also been identified at other measurement points in the electrical power supply system. It is likewise possible to link all the data records which have been produced by the electrical field devices and have been emitted to the communication network to form an overall data record which provides an overview of the state of the entire electrical power supply system. The communication network may advantageously be an IP-compatible network, for example an Ethernet network, in which, for example, data is interchanged in accordance with IEC Standard 61850.

It may also be advantageous to connect a central data processing facility to the communication network. The individual data records or an entire data record can be indicated and evaluated by means of the central data processing facility.

In order to explain the invention further:

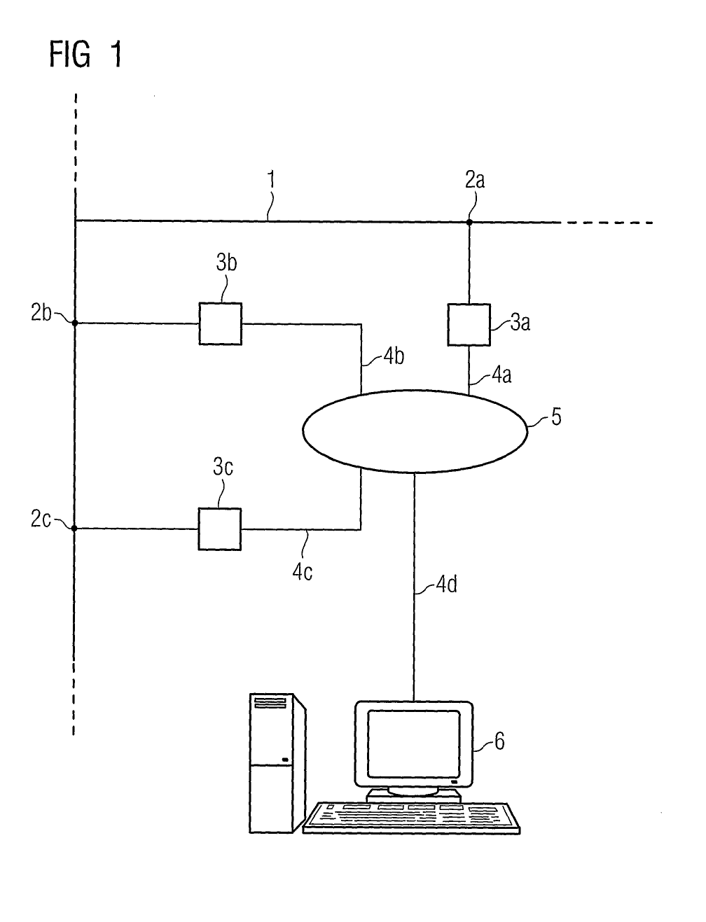

FIG. 1 shows one exemplary embodiment of a system comprising a plurality of field devices for recording the electrical power quality in a power supply system,

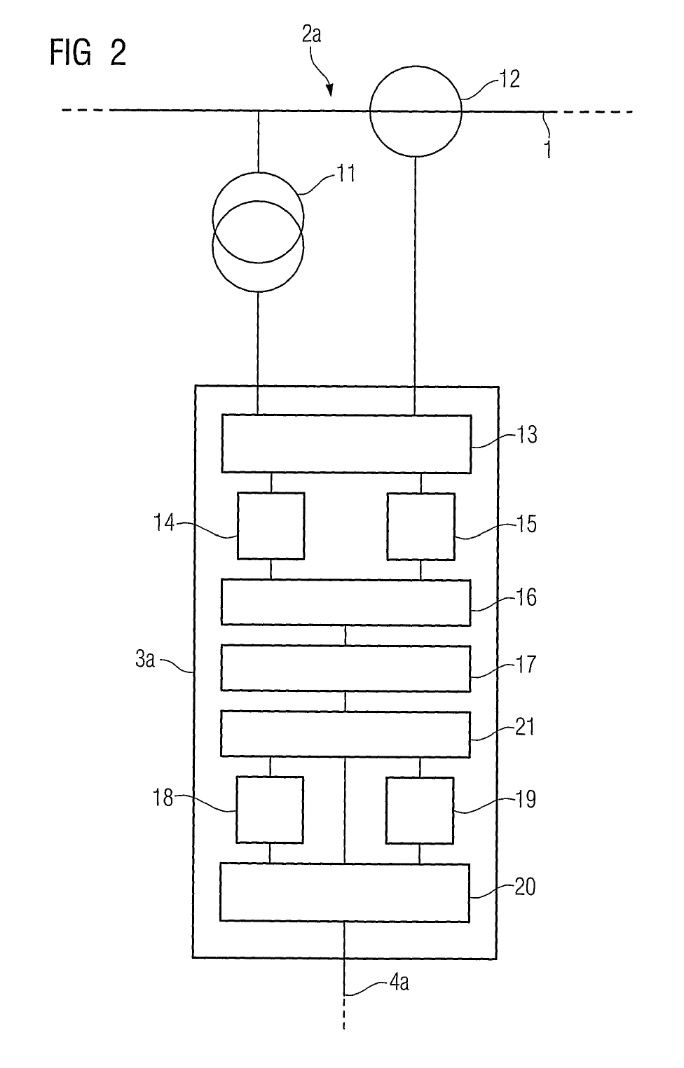

FIG. 2 shows one exemplary embodiment of an electrical field device for recording the electrical power quality in a power supply system, and

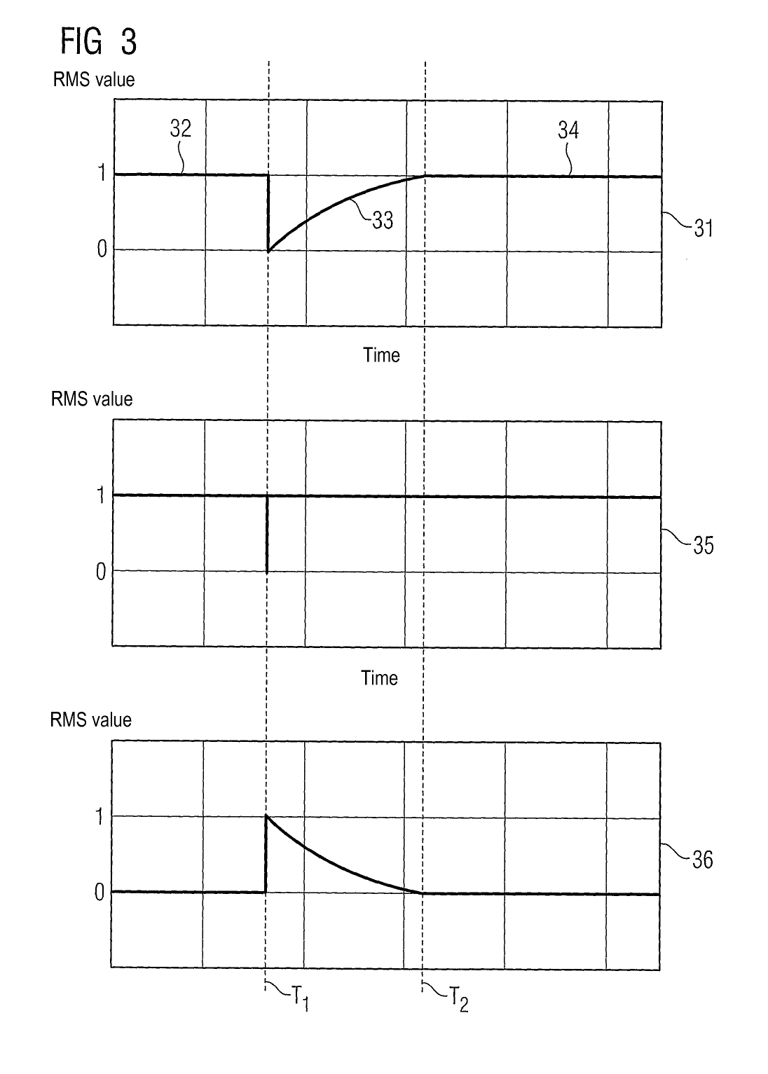

FIG. 3 shows three graphs in order to explain the way in which an event signal is produced.

In FIG. 1, 1 denotes an electrical power supply system of which, by way of example, two sections are illustrated here, for example a busbar and an outgoer connected to it. Current transformers and/or voltage transformers, which are not illustrated in FIG. 1, are provided at a plurality of measurement points 2a to 2c in the electrical power supply system 1 and are connected on the output side to electrical field devices 3a to 3c for recording the electrical power quality in the electrical power supply system 1. The electrical field devices 3a to 3c are themselves connected via data lines 4a to 4c to a communication network 5, for example to an Ethernet network. A central data processing facility 6 is also connected to the communication network 5 via a communication line 4d.

The system as illustrated in FIG. 1 operates as explained in the following text: The field devices 3a to 3c record measured values via the current transformers and voltage transformers that are not illustrated, indicating the alternating-current and/or AC voltage values at the respective measurement points 2a, 2b and 2c in the electrical power supply system 1. The recorded measured values are then checked to determine whether there is any discrepancy between the measured values, and therefore also in the alternating-current or AC voltage values at the respective measurement points 2a to 2c in the electrical power supply system. In this case, a discrepancy is regarded as a difference between the alternating-current or AC voltage values and their required profile. The electrical field devices 3a to 3c use the recorded measured values to determine a possible cause of the respective discrepancy, and indicate this in the form of a cause character string. In addition, it is possible to provide for the electrical field devices to also determine possible effects of the discrepancies at the respective measurement points 2a to 2c, and to indicate these in the form of an effect character string. The cause character string, and possibly the effect character string and further state parameters produced from the measured values which indicate the respective state of the electrical power supply system at the individual measurement points 2a to 2c are used as the basis for production of a data record which specifies the identified discrepancy in more detail. The field devices produce data records such as these and then transmit them via the data lines 4a to 4c to the communication network 5. If, for example, the communication network 5 is an Ethernet network, then this data transmission can take place in accordance with IEC Standard 61850, which relates to field device communication.

The individual data records of the respective field devices 3a to 3c can be combined to form an overall data record, which makes it possible to provide an overview of all the relevant measurement points in the electrical power supply system. This can be done either in one of the field devices 3a to 3c or in the central data processing facility 6. Finally, either the individual data records or an overall data record produced by one of the field devices 3a to 3c is transmitted to the data processing facility 6, where further indication and evaluation of the identified discrepancy in the electrical power quality can be carried out.

FIG. 2 shows an example of the field device 3a in more detail. The electrical field device 3a is connected via a voltage transformer 11 and a current transformer 12 to a measurement point 2a in the electrical power supply system 1. On the input side, the electrical field device 3a has a measurement device 13 which is connected to the voltage transformer 11 and to the current transformer 12, and is connected on the output side to a computation unit 14 and an estimation unit 15. The computation unit 14 and the estimation unit 15 are themselves connected on their output sides to a subtractor 16. The output side of the subtractor 16 itself is connected to an event identification device 17. The event identification device 17 is followed by a parameter calculation device 21, on its output side.

The parameter calculation device 21 is followed on its output side firstly by a cause identification unit 18 and secondly by an effect identification device 19. The cause identification unit 18 and the effect identification device 19 are themselves connected on their output sides to an output unit 20 which is in turn connected at its output by means of a data interface and via the data line 4a to the communication network 5 illustrated in FIG. 1.

If the electrical power supply system 1 is a polyphase power supply system, for example a three-phase power supply system, then a current transformer and a voltage transformer and a corresponding number of functional components of the electrical field device 3a, for example of the measurement device 13, are provided as appropriate for each phase.

The method of operation of the field device 3a illustrated in FIG. 2 will be explained in more detail in the following text: Alternating-current and/or AC voltage values which occur at the measurement point 2a in the electrical power supply system 1 are converted via the current transformer 12 or the voltage transformer 11, respectively, to measured values which are proportional to the alternating-current values or AC voltage values, respectively, and are recorded by the measurement device 13 in the field device 3a. For example, the measured values can also be converted from analog to digital form in the measurement device 13. However, the analog to digital conversion process may also be carried out outside the electrical field device 3a.

The recorded measured values are passed to the computation unit 14 which uses the measured values to produce a mean value, for example a root mean square (RMS) value. For this purpose, it is advantageous for the measured values to be recorded during a time period of, for example, in each case half the oscillation period of the alternating current or AC voltage, and/or the mean value to be formed from the measured values recorded during this half oscillation period. On the one hand, this results in sufficient measured values for reliable calculation, and on the other hand it allows the mean value to be determined relatively quickly.

The estimation device 15 is likewise connected to the measurement device 13 and, on the basis of previous measured values, emits an estimate of what the assumed expected mean value should be. By way of example, a signal model implemented by electronic or digital filters and with a DC voltage component and an exponential component can be used for this purpose. The DC voltage component records the constant components of the mean value, while the exponential component determines exponentially rising or falling components of the mean value. FIG. 3 will be considered first of all in order to explain the method of operation of the estimation device 15.

Three graphs are shown in FIG. 3. A bold solid line in the upper graph 31 shows the profile of a mean value, determined in the computation unit 14, of the AC voltage or the alternating current. The time profile of the mean value can be subdivided into three sections. The first section 32 shows a constant profile of the RMS value. At the time T1 indicated by a first dashed line, the value of the mean value falls suddenly in order then to rise again exponentially in a second section 33 of the profile of the mean value. After the time T2 indicated by a further dashed line, the value of the mean value once again returns to its original value, and is constant again in a third section 34.

The central graph 35 illustrated in FIG. 3 shows the profile of a constant component of the time profile of the mean value illustrated in the first graph. This shows an essentially constant profile, which has a sudden deflection just at the time T1.

Finally, the lower graph 36 in FIG. 3 shows the exponential component of the time profile of the mean value as illustrated in graph 31. As can be seen, the exponential component is zero in the sections 32 and 34, that is to say the profile of the mean value has no exponential component in these sections. An exponential component of the mean value profile over time from the upper graph exists only in the section 33 between the times T1 and T2. If the exponential profile is subtracted from the constant component, then this once again results in the time profile of the mean value as indicated in the upper graph 31.

The estimation unit 15 (see FIG. 2) operates as follows. In the first section 32 of the time profile of the mean value, the estimation unit 15 identifies only a constant component of the time profile, and therefore predicts that the expected value will be a continuation of the constant component at the same value. Both the computation unit 14 and the estimation unit 15 pass their results to the subtractor 16, which substracts the expected value from the actual mean value. In the case of the first section 32, the resultant difference is a value close to zero, so that the event identification device 17 does not indicate any discrepancy between the mean value and its expected profile, and therefore does not produce any event signal. By way of example, the event identification device can carry out a threshold value comparison process for this purpose. If the difference determined by the subtractor is above a predeterminable threshold, for example 5% of the previous value of the mean value, then the event identification device 17 identifies a discrepancy and produces an event signal.

The actual mean value changes suddenly at the time T1. However, on the basis of the mean values prior to this time T1, the estimation device 15 determines an expected value which still has a constant profile at the time T1 in the region 32. This therefore results in a difference value in the subtractor 16 which is not equal to zero, and this is supplied to the event identification device 17. In the present case, it is assumed that the calculated difference is greater than the predetermined threshold value, so that the event identification device 17 identifies a discrepancy, and accordingly emits an event signal.

Since the further profile of the actual mean value has an exponential profile, the estimation module is reinitialized and now emits expected values which follow a exponential profile. Because the actual mean value emitted by the computation unit 14 and the expected value emitted by the estimation unit 15 now match one another again, the subtractor 16 calculates a difference close to zero, and this is below the threshold value used by the event identification device 17. After identification of the discrepancy at the time T1, further measured values are recorded throughout a predeterminable measurement period, with mean values also being formed from these further measured values. Thus, in consequence, once the event identification device 17 has emitted the event signal, for example, further measured values are recorded for a predetermined measurement time of 5 seconds, with mean values also in each case being formed from the further measured values for time windows with a period of half the oscillation period of the alternating current or of the AC voltage.

Furthermore, a parameter calculation device 21 which follows the event identification device 17 uses the measured values recorded during this measurement time to form a set of state parameters which describe the state of the electrical power supply system at the measurement point 2a during the event time period. This will be described in more detail later.

As the mean value progresses further, the mean value once again assumes the original constant value in the section 34 (FIG. 3) since, here, the exponential component of the profile is decayed again. In consequence, the estimation unit 15 still produces expected values which match the actual mean value emitted by the computation unit 14. The subtractor 16 therefore determines a difference close to zero in the section 34, which leads to the event identification device 17 not emitting any event signal.

The state parameters which are calculated by the parameter calculation device 21 during the measurement time may, for example, be balanced components, harmonic components and frequencies, phases and amplitudes of the alternating-current or AC voltage values. They describe the state of the power supply system at the measurement point 2a. The state parameters are supplied to the cause identification unit 18. The cause identification unit 18 has a database which contains possible causes for discrepancies in the alternating-current and/or AC voltage profile at the measurement point 2a and associates each possible cause with in each case one comparison set of state parameters. That parameter set which has been calculated by the parameter calculation device 21 is in consequence compared with the comparison sets in the database. If a comparison set matches the parameter set, it is possible to deduce the cause of the discrepancy on which this is based. In this case, a cause character string is read from the database, and the cause identification unit produces this on its output side.

By way of example, the electronic database for the cause identification unit 18 may be configured as indicated by the following table:

| | | Number of | | | |
|---|---|---|---|---|---|
| | RMS (of the | event signals | Balanced | | |
| Cause | AC voltage | produced | components | Harmonics | Duration |
| Fault (for | steep drop | 2 | balanced or | No influence | Very long |
| example | steep | | unbalanced | | [several |
| short) | linear | | | | periods] |
| | profile | | | | |
| | steep rise | | | | |
| | again | | | | |
| Motor start | steep drop | 1 | balanced | No influence | Very long |
| | presence of | | | | [several |
| | a minimum | | | | periods] |
| | exponential | | | | |
| | rise again | | | | |
| Transformer - | steep drop | 1 | unbalanced | Second | Very long |
| start | presence of | | | harmonic | |
| | a minimum | | | component | |
| | exponential | | | greater than | |
| | rise again | | | 10% | |
| Continuing | steep drop | >2 | balanced or | No influence | Very long |
| faults | multiple | | unbalanced | | [several |
| | occurrence of | | | | periods] |
| | stable linear | | | | |
| | profiles | | | | |
| | steep rise | | | | |
| | again | | | | |
| Self- | steep drop | 1 | unbalanced | No influence | Very short |
| correcting | presence of | | | | |
| faults | a minimum, | | | | |
| | exponential | | | | |
| | rise again | | | | |

On the basis of the illustrated table, the cause identification unit 18 would identify, on the basis of the time profile of the mean value illustrated in the upper graph 31 in FIG. 3 in conjunction with the further calculated state parameters, that the cause is the starting of an electric motor and would in consequence emit as the cause character string, for example, “starting of an electric motor”.

In addition to determining a cause of the discrepancy that has occurred, it is also possible to determine effects of the discrepancy that has occurred. This is done in the effect identification device 19, to which the parameter set of state parameters is likewise passed. The effect identification device 19 uses the state parameters “magnitude of the discrepancy” and “event duration” (=duration of the discrepancy) which are plotted on a graph with ITIC reference curves, for example, to determine the severity of the discrepancies and indicates possible damage to loads connected to the power supply system, in particular loads in the information-technology area. The effect identification device 19 outputs these effects in the form of an effect character string. Both the cause character string and any effect character string which may be produced as well as the state parameters produced in the parameter calculation device 21 are used as the basis for production of a data record. This data record may either specifically contain the cause character string, the effect character string and the state parameters or information derived from them. This data record can be transmitted via the data interface of the input unit 20 and the communication line 4a to the communication network 5 which, for example, may be an Ethernet network, and, for example, may be received by the central data processing facility 6 illustrated in FIG. 1. The central data processing facility 6 can indicate the data record to a user who is in this way comprehensively informed of the discrepancy that has occurred, without any need to carry out any further evaluation processes.

Although the components of the electrical field device 3a which have been explained in conjunction with FIG. 2 are illustrated in the form of separate functional blocks, they may also be in the form of a microprocessor device for the electrical field device, which provides appropriate software by means of which the individual method steps are carried out.

1-20. (canceled)

21. A method of producing a data record indicating a deviation of alternating current and/or AC voltage values at a measurement point in a power supply system from an expected time profile, the method which comprises:
recording measured values indicating the alternating current and/or AC voltage values at the measurement point in the power supply system;
if the measured values differ from the expected time profile, generating an event signal;
if an event signal is present, determining a parameter set of state parameters describing a state of the power supply system at the measurement point) from the measured values and from further measured values following the measured values during a predetermined measurement period, and associating at least some of the state parameters in the parameter set with an associated cause character string indicating a cause of the deviation; and
generating the data record from at least the parameter set and the cause character string.

22. The method according to claim 21, which comprises:
recording the measured values in each case during an averaging period and forming a mean value from the measured values recorded during the averaging period;
forming a difference between the mean value and an expected value, with the expected value indicating an expected value of the mean value that has been determined with respect to the actual mean value of mean values from previous times; and
generating the event signal which indicates a deviation in the mean value if the difference exceeds a predetermined threshold value.

23. The method according to claim 22, wherein the averaging period is half an oscillation period of the measured alternating current or of the measured AC voltage.

24. The method according to claim 21, wherein the step of associating the state parameters with the cause character string comprises:
using an electronic database in which in each case one cause character string is associated with an associated comparison set of state parameters; and
generating the data record from a cause character string having an associated comparison set matching the determined parameter set.

25. The method according to claim 21, wherein the parameter set indicates harmonic oscillations of a fundamental frequency of the measured values.

26. The method according to claim 21, wherein the power supply system is a three-phase power supply system, and the parameter set includes balanced components of the measured values.

27. The method according to claim 21, which comprises determining an event time duration during which the deviation is present, and generating the parameter set to also indicates the event time duration.

28. The method according to claim 21, which comprises:
using at least some of the state parameters in the parameter set to produce an effective character string which indicates an effect of the discrepancy; and
producing the data record taking into account the effect character string.

29. The method according to claim 21, which comprises:
carrying out the method at a plurality of measurement points in the power supply system and producing a plurality of data records; and
combining the plurality of the data records produced at the individual measurement points to form an overall data record.

30. A field device for recording the electrical power quality at a measurement point in a power supply system, comprising:
a measurement device for recording measured values indicating an alternating current and/or an AC voltage;
an event identification device configured to receive and use the measured values to identify a deviation of the alternating current and/or the AC voltage from an expected profile;
a parameter calculation device for determining a parameter set of state parameters from the measured values and from further measured values following the measured values during a predeterminable measurement period, the state parameters indicating a state of the power supply system at the measurement point;
a cause identification unit configured to allocate a cause character string, indicating a cause of the deviation, when a discrepancy of the parameter set exists; and
an output unit for outputting a data record formed taking into account at least some of the state parameters in the parameter set and the cause character string.

31. The field device according to claim 30, which further comprises:
a computation unit for determining a mean value of the recorded measured values; and
wherein said event identification device is configured to identify any discrepancy between the mean value and an expected profile thereof.

32. The field device according to claim 30, wherein said cause identification unit includes an electronic database having one cause character string each associated with an associated comparison set of state parameters.

33. The field device according to claim 30, which further comprises an effect identification device configured to use at least some of the state parameters to produce an effect character string indicating an effect of the deviation.

34. The field device according to claim 30, wherein said output unit has a data interface for outputting the data record.

35. The field device according to claim 34, wherein said data interface is an interface for an Internet protocol-compatible network.

36. The field device according to claim 35, wherein said data interface is an Ethernet interface.

37. A system for recording the electrical power quality of a power supply system, comprising:
a plurality of field devices according to claim 30; and
a communication network connecting said field devices to one another.

38. The system according to claim 37, wherein said communication network is an IP-compatible network.

39. The system according to claim 38, wherein said communication network is an Ethernet network.

40. The system according to claim 37, which further comprises a central data processing facility connected to said communication network.
